(19) United States
(12) Patent Application Publication
(10) Pub. No.: US 2015/0156882 A1
(43) Pub. Date: Jun. 4, 2015

(54) PRINTED CIRCUIT BOARD, MANUFACTURING METHOD THEREOF, AND SEMICONDUCTOR PACKAGE

(71) Applicant: SAMSUNG ELECTRO-MECHANICS CO., LTD., Suwon (KR)

(72) Inventors: Kang Wook BONG, Suwon (KR); Jin Won Lee, Suwon (KR)

(73) Assignee: SAMSUNG ELECTRO-MECHANICS CO., LTD., Suwon (KR)

(21) Appl. No.: 14/334,819

(22) Filed: Jul. 18, 2014

(30) Foreign Application Priority Data
Dec. 4, 2013 (KR) 10-2013-0150063

(51) Int. Cl. H05K 1/18; H05K 3/46; H01L 23/00; H05K 3/42; H05K 3/04; H05K 1/02; H05K 3/30

(52) U.S. Cl. CPC H05K 1/184; H05K 1/0298; H05K 3/4673; H05K 3/305; H05K 3/429; H05K 3/045; H01L 24/10; H01L 24/11; H01L 2224/10; H01L 2224/11; H01L 2924/01029

(57) ABSTRACT

A printed circuit board may include a circuit pattern serving as a land. The circuit pattern may be embedded inside a via to forma larger amount of circuits within a limited region. Also, by implementing a shortest distance between an embedded electronic component and a surface mounting component, noise may be reduced and electrical characteristics may be enhanced.

### CROSS-REFERENCE TO RELATED APPLICATION

This application claims the benefit of Korean Patent Application No. 10-2013-0150063 filed on Dec. 4, 2013, with the Korean Intellectual Property Office, the disclosure of which is incorporated herein by reference.

### BACKGROUND

The present disclosure relates to a printed circuit board (PCB), a manufacturing method thereof, and a semiconductor package.

Developments within the electronics industry have been triggered by growing demand for highly efficient, multifunctional, miniaturized electronic components. To meet demand therefor, high density boards for surface-mounted components such as semiconductor packages, and the like, have emerged and an embedded PCB technology for embedded devices inside PCBs has been developed.

To meet the demand for high density boards, circuit patterns need to be connected with high density between layers. According to a plating technique, a via hole is processed and an inner circumferential surface of the via hole is plated or the via hole is filled with a plating layer to implement interlayer connectivity. However, the aforementioned related art has limitations in terms of the formation of high density interlayer connections, so it cannot be applied to manufacturing as a complete production technology.

Thus, a structure in which high density circuits are implemented through forming interlayer connections between circuit patterns having high degrees of density or increasing a degree of freedom in circuit design is required.

Meanwhile, in order to implement an embedded PCB, after an embedding process is performed through a package of a device, electrical conductivity needs to be provided. Recent embedding techniques require the implementation of microcircuits for high integration when electronic components are embedded.

Thus, a thin structure that allows for surface-mounted components to be embedded therein, while allowing for the implementation of microcircuits, is required.

### RELATED ART DOCUMENT

(Patent Document 1) Japanese Patent Laid-Open Publication No. 2008-160144

### SUMMARY

An exemplary embodiment in the present disclosure may provide a printed circuit board (PCB) in which a circuit pattern serving as a land is embedded inside a via and the shortest connection distance is implemented between embedded electronic components and surface-mounted components, reducing noise and enhancing electrical characteristics, a manufacturing method thereof, and a semiconductor package.

According to an exemplary embodiment in the present disclosure, a printed circuit board may include: an insulating layer; a first circuit layer including a first circuit pattern embedded therein such that an upper surface thereof is exposed to a first surface of the insulating layer; a second circuit layer including a second circuit pattern formed on a second surface of the insulating layer; a via electrically connecting the first circuit pattern and the second circuit pattern and formed in the insulating layer such that the first circuit pattern is embedded; and an electronic component embedded inside the insulating layer and having an upper surface exposed to the first surface of the insulating layer.

A level of the top surface of first circuit pattern may be equal to or lower than that of the insulating layer.

The first circuit pattern may serve as a land.

A width of the first circuit pattern may be smaller than or equal to a diameter of the via.

The first circuit pattern and the via may be formed of the same material.

The electronic component may be embedded such that a level of an upper surface thereof is equal to or lower than a level of the insulating layer.

A via may be formed in a lower surface of the electronic component and electrically connected to the second circuit pattern.

The PCB may further include a solder bump formed on the exposed surface of the electronic component; and an external mounting device formed on the solder bump so as to be mounted.

The PCB may further include: a solder resist formed to expose a circuit pattern for a connection pad of the first circuit layer and the second circuit layer and the external electrode of the electronic component.

The PCB may further include: a build-up layer stacked on the second surface of the insulating layer.

According to an exemplary embodiment in the present disclosure, a semiconductor package may include: an insulating layer; a first circuit layer including a first circuit pattern embedded therein such that an upper surface thereof is exposed to a first surface of the insulating layer; a second circuit layer including a second circuit pattern 132 formed on a second surface of the insulating layer; a via electrically connecting the first circuit pattern and the second circuit pattern and formed in the insulating layer such that the first circuit pattern is embedded; a stacked-type electronic component embedded inside the insulating layer and having an external electrode exposed to the first surface of the insulating layer; a solder bump formed on the external electrode; and a surface mounting component formed on the solder bump so as to be mounted.

According to an exemplary embodiment in the present disclosure, a method of manufacturing a printed circuit board (PCB) may include: preparing a carrier board having a least one surface on which a first metal layer is formed; forming a first circuit layer including a first circuit pattern and an electronic component on at least one surface of the first metal layer; forming an insulating layer on the first circuit layer and the electronic component; forming a via hole such that the first circuit pattern and an external electrode of the electronic component are exposed; forming a via and a patterned metal plating layer such that the first circuit pattern is embedded and the external electrode is electrically connected; delaminating the first metal layer from the carrier board; and removing the first metal layer to expose the first circuit layer and the electronic component.

A level of the top surface of first circuit pattern may be equal to or lower than that of the insulating layer.

The first circuit pattern may serve as a land.

A width of the first circuit pattern may be smaller than or equal to a diameter of the via.

The via and the first circuit pattern may be formed of the same material.

The method may further include: forming a second circuit layer on a surface of the insulating layer opposite a surface on which the first circuit layer is formed; and forming a build-up layer on the second circuit layer.

An electronic component may be attached using an adhesive tape on both surfaces of the first metal layer.

The adhesive tape may be removed when the first metal layer is removed.

According to an exemplary embodiment in the present disclosure, a method of manufacturing a printed circuit board (PCB) may include: preparing a carrier board having a least one surface on which a first metal layer is formed; forming a first circuit layer including a first circuit pattern and an electronic component on at least one surface of the first metal layer; forming an insulating layer on the first circuit layer and the electronic component; forming a via hole such that the first circuit pattern and an external electrode of the electronic component are exposed; forming a via and a patterned metal plating layer such that the first circuit pattern is embedded and the external electrode is electrically connected; delaminating the first metal layer from the carrier board; removing the first metal layer to expose the first circuit layer and the electronic component and forming a second circuit layer including a second circuit pattern; forming a solder bump on an exposed surface of the electronic component; and mounting a surface mounting component on the solder bump.

According to an exemplary embodiment in the present disclosure, a printed circuit board (PCB) may include: an insulating layer; an electronic component embedded in the insulating layer; and a solder bump formed on an electrode of the electronic component.

A solder resist may be formed in at least a portion of the electronic component.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view illustrating a structure of a printed circuit board (PCB) according to an exemplary embodiment of the present disclosure;

FIG. 2 is a cross-sectional view illustrating a structure of a semiconductor package according to an exemplary embodiment of the present disclosure;

FIG. 3 is a cross-sectional view illustrating a structure of a semiconductor package according to an exemplary embodiment of the present disclosure;

FIGS. 4 through 14 are cross-sectional views sequentially illustrating a method for manufacturing a PCB according to an exemplary embodiment of the present disclosure; and

FIGS. 15 and 16 are cross-sectional views sequentially illustrating a method for manufacturing a semiconductor package according to an exemplary embodiment of the present disclosure.

### DETAILED DESCRIPTION

Hereinafter, embodiments in the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

Printed Circuit Board

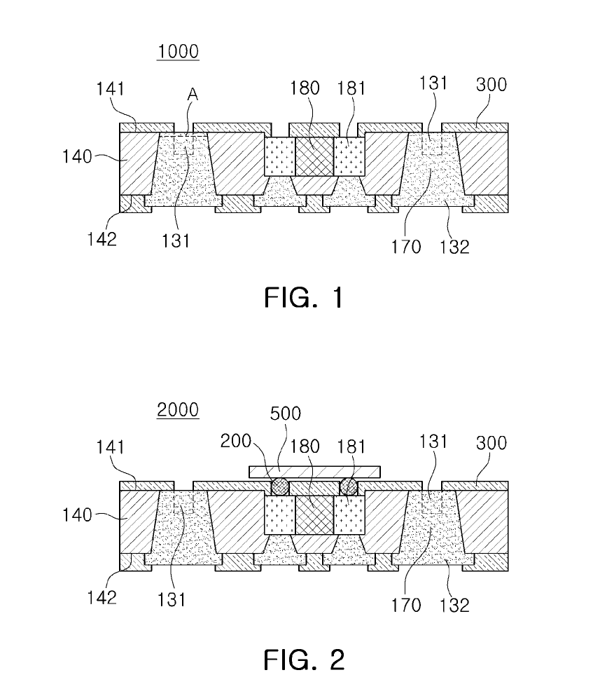

FIG. 1 is a cross-sectional view illustrating a structure of a printed circuit board (PCB) according to an exemplary embodiment of the present disclosure.

Referring to FIG. 1, a PCB 1000 according to an exemplary embodiment of the present disclosure includes an insulating layer 140, a first circuit layer including a first circuit pattern 131 embedded such that an upper surface thereof is exposed to a first surface 141 of the insulating layer 140, a second circuit layer including a second circuit pattern 132 formed on a second surface 142 of the insulating layer 140, a via 170 electrically connecting the first circuit pattern 131 and the second circuit pattern 132 and formed in the insulating layer 140 such that the first circuit pattern 131 is embedded, and an electronic component 180 embedded inside the insulating layer 140 and having an upper surface exposed to the first surface 141 of the insulating layer 140.

A resin insulating layer may be used as the insulating layer 140. The resin insulating layer may be formed of a thermosetting resin such as an epoxy resin, a thermoplastic resin such as polyimide, or a resin obtained by impregnating any of these resins with a reinforcing material such as glass fiber or an inorganic filler, for example, prepreg. Also, a thermosetting resin and/or a photocurable resin, or the like, may be used as a material of the resin insulating layer but the present disclosure is not limited thereto.

In the circuit board field, any circuit layer may be applied without a limitation as long as the circuit layer is formed of a conductive metal for a circuit, and typically, copper is used in a PCB.

A surface-treated layer (not shown) may be further formed on the exposed circuit layer as needed.

The surface-treated layer may be formed through, for example, a method such as electro-gold plating, immersion gold plating, organic solderability preservative (OSP) process, immersion tin plating, immersion silver plating, electroless nickel and immersion gold (ENIG) plating, direct immersion gold (DIG) plating, hot air solder leveling (HASL), or the like, but the present disclosure is not limited thereto and any method may be used as long as the method is known in the art.

Here, the first circuit pattern 131 may be formed to serve as a land, whereby the first circuit pattern 131 may be embedded inside the via 170 to form a larger amount of circuits within a limited region, manufacturing a high density product.

Also, by forming the first circuit pattern 131 such that a width thereof is equal to or smaller than a diameter of the via 170, only an upper surface of the first circuit pattern 131 is exposed outwardly and the other remaining three sides of the first circuit pattern 131, excluding the upper surface, are embedded inside the via 170, enhancing electrical characteristics and reliability of the semiconductor package.

The via 170 may be formed of a material identical to that of the first circuit pattern 131. Typically, copper (Cu) is used, but any material may be applied without a limitation as long as it is used as a conductive metal.

In the drawing, the via 170 is illustrated as having a tapered shape having a diameter increasing toward a lower surface, but the via may be formed to have any shape known in the art, such as a tapered shape having a diameter decreasing toward the lower surface, a cylindrical shape, or the like.

A level of the exposed upper surface of the first circuit pattern 131 is equal to or lower than that of the insulating layer 140, and when a level of the first pattern 131 is lower than that of the insulating layer 140, a step may be formed (please refer to the dotted line A).

Here, due to the step, solder is prevented from being fixed to be bridged with adjacent solder during a reflow process of forming a solder bump 200 on the first circuit pattern 131.

A level of an exposed upper surface of the electronic component 180 may be equal to or lower than that of the insulating layer 140, so as to be embedded.

The solder bump 200 may be directly formed on an external electrode 181 on the exposed upper surface of the electronic component 180, and an external mounting device may be formed on the solder bump 200.

In the related art, an embedded electronic component is connected through via and a solder bump is formed on the via and connected to an external mounting device. In contrast, according to an exemplary embedment of the present disclosure, since the embedded electronic component is directly connected to an external mounting device through the solder bump, a shortest distance may be secured, enhancing electrical characteristics.

A via may be formed in a lower surface of the electronic component 180 to electrically connect the external electrode 181 and the second circuit pattern 132.

A solder resist 300 may be formed on a surface of the PCB to expose a circuit pattern for a connection pad of the first circuit layer and the second circuit layer and the external electrode 181 of the electronic component 180.

FIG. 2 is a cross-sectional view illustrating a structure of a semiconductor package according to an exemplary embodiment of the present disclosure.

Referring to FIG. 2, a semiconductor package 2000 according to an exemplary embodiment of the present disclosure includes an insulating layer 140, a first circuit layer including a first circuit pattern 131 embedded such that an upper surface thereof is exposed to a first surface 141 of the insulating layer 140, a second circuit layer including a second circuit pattern 132 formed on a second surface 142 of the insulating layer 140, a via 170 electrically connecting the first circuit pattern 131 and the second circuit pattern 132 and formed in the insulating layer 140 such that the first circuit pattern 131 is embedded, a stacked-type electronic component 180 embedded inside the insulating layer 140 and having an external electrode 181 exposed to the first surface 141 of the insulating layer 140, a solder bump 200 formed on the external electrode 181, and a surface mounting component 500 formed on the solder bump 200 so as to be mounted.

The surface mounting component 500 may be a component electrically connected to a PCB to provide a predetermined function. For example, the surface mounting component 500 may be an electronic component that may be directly mounted on a PCB, such as an integrated circuit (IC).

Other components of the surface mounting component 500 are omitted in the drawing, but electronic components having any structure known in the art may be used without a limitation.

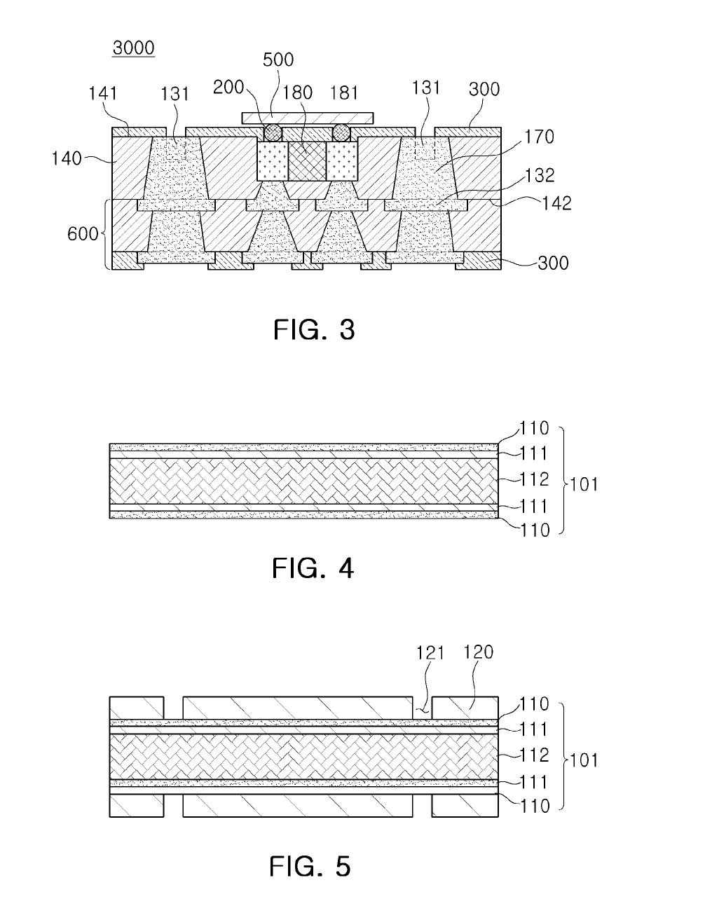

FIG. 3 is a cross-sectional view illustrating a structure of a semiconductor package according to an exemplary embodiment of the present disclosure.

Referring to FIG. 3, the semiconductor package 3000 according to an exemplary embodiment of the present disclosure may further include a build-up layer 600 stacked on the second surface 142 of the insulating layer 140.

In the drawing, the build-up layer 600 stacked on the second surface 142 of the insulating layer 140 is illustrated as a dual-layer including a build-up insulating layer and a build-up circuit layer, but the build-up layer 600 may also be formed as a triple layer or a quadruple layer, or may be formed within the scope utilized by a person skilled in the art.

Method of Manufacturing PCB

FIGS. 4 through 14 are cross-sectional view sequentially illustrating a method for manufacturing a PCB according to an exemplary embodiment of the present disclosure

Referring to FIG. 4, first, a carrier substrate 101 is prepared.

The carrier substrate 101 may include a core 112, metal layers 111 formed on both surfaces of the core 112, and first metal layers 110 respectively formed on the metal layers 111.

The metal layers 111 and the first metal layers 110 may be formed of copper (Cu), but the present disclosure is not limited thereto. At least one of facing surfaces of the metal layers 111 and the first metal layers 110 may be surface-treated so as to be easily separated.

Referring to FIG. 5, a resist layer 120 having an opening 121 for forming a circuit may be formed on the first metal layer 110.

The resist layer 120 may generally be photosensitive resist films, and dry film resist, or the like, may be used, but the present disclosure is not limited thereto.

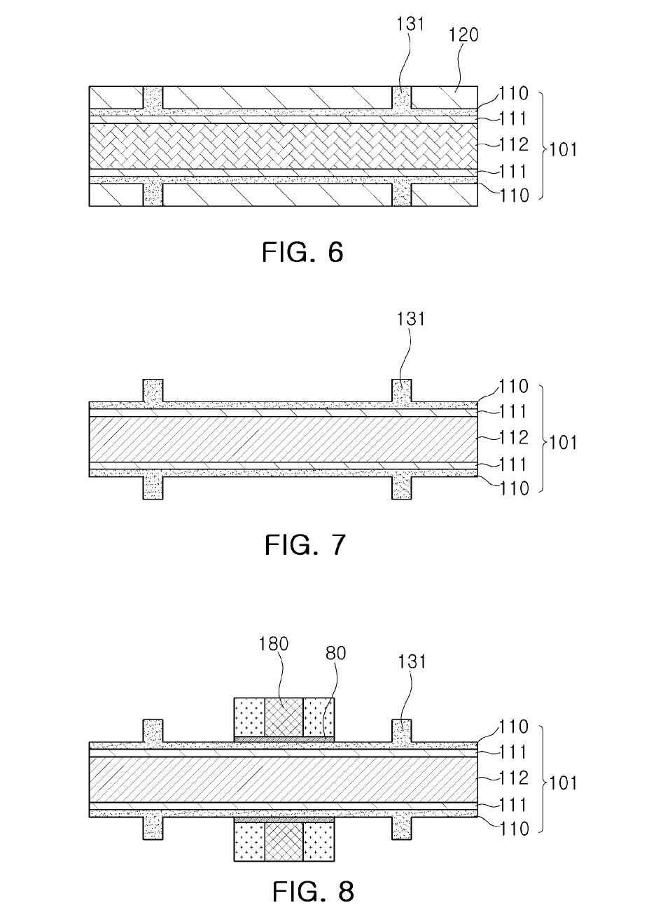

Referring to FIG. 6, the opening 121 for forming a circuit is filled with a metal to form a first circuit layer including a first circuit pattern 131 by applying a process such as plating, or the like.

The circuit layer may be formed of any material as long as it may be used as a conductive metal for a circuit without a limitation. For example, copper (Cu) is typically used in a PCB.

Referring to FIG. 7, after the first circuit layer is formed, the resist layer 120 for forming a circuit may be removed.

Referring to FIG. 8, an electronic component 180 may be formed on the first metal layer 110. The electronic component 180 maybe fixed using an adhesive such as an adhesive tape 80, or the like.

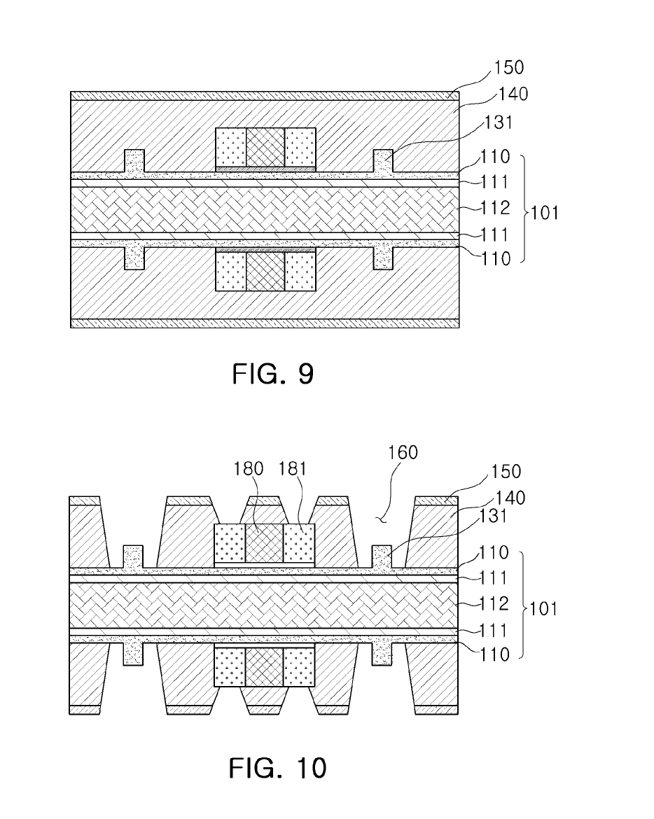

Referring to FIG. 9, an insulating layer 140 and a second metal layer 150 may be sequentially formed on the first circuit layer and the electronic component 180.

A resin insulating layer may be used as the insulating layer 140. The resin insulating layer may be formed of a thermosetting resin such as an epoxy resin, a thermoplastic resin such as polyimide, or a resin obtained by impregnating any of these resins with a reinforcing material such as glass fiber or an inorganic filler, for example, prepreg. Also, a thermosetting resin and/or a photocurable resin, or the like, may be used as a material of the resin insulating layer but the present disclosure is not limited thereto.

Referring to FIG. 10, a via hole 160 may be formed in the second metal layer 150 and the insulating layer 140 such that the first circuit pattern 131 and the external electrode 181 of the electronic component 180 are exposed.

The via hole 160 may be formed using mechanical drill or laser drill, but the present disclosure is not limited thereto. Here, the laser drill may be CO₂ laser or YAG laser, but the present disclosure is not limited thereto.

In the drawing, the via hole 160 is illustrated as having a tapered shape having a diameter decreasing toward a lower surface, but the via may be formed to have any shape known in the art, such as a tapered shape having a diameter increasing toward the lower surface, a cylindrical shape, or the like.

Here, when the via hole 160 is formed, a width of the first circuit pattern 131 may be equal to or smaller than a diameter of the via hole 160.

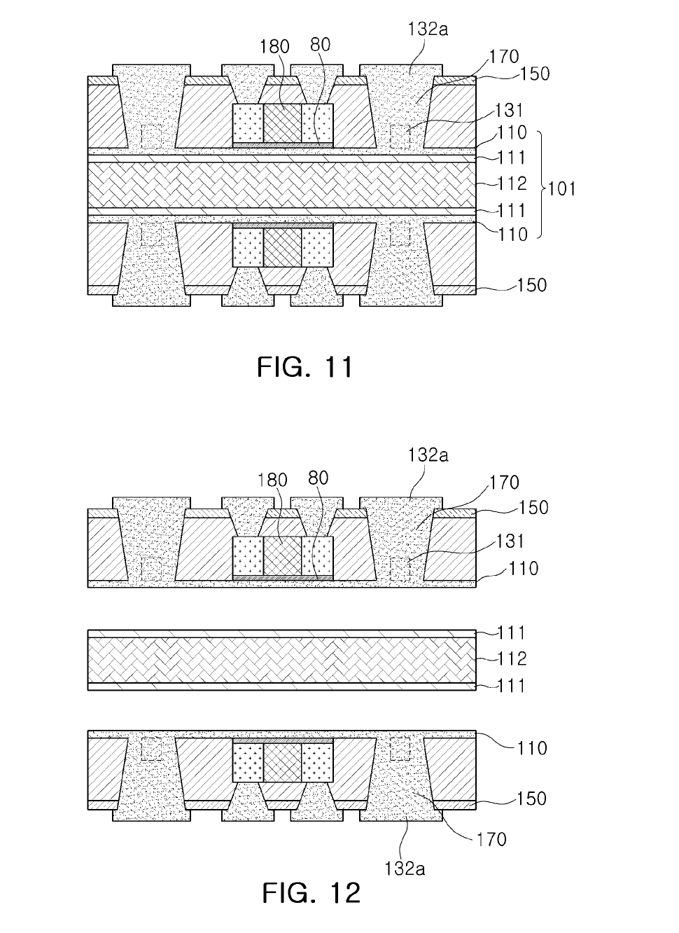

Referring to FIG. 11, a via 170 and a patterned metal plating layer 132a may be formed such that the first circuit pattern 131 is embedded and the external electrode 181 of the electronic component 180 is electrically connected.

A metal filling the via 170 may be a material identical to that of the embedded first circuit pattern 131.

Here, since the first circuit pattern 131, replacing a land, exists inside the via hole 160, an advantageous effect may be obtained for a via fill in metal filling.

Here, only an upper surface of the first circuit pattern 131 is exposed outwardly and the other remaining three sides of the first circuit pattern 131, excluding the upper surface, are embedded inside the via 170, enhancing electrical characteristics and reliability of the semiconductor package.

Also, the first circuit pattern 131 may be formed to serve as a land, whereby the first circuit pattern 131 may be embedded inside the via hole 160 to form a larger amount of circuits within a limited region, manufacturing a high density product.

Referring to FIG. 12, the metal layer 111 and the first metal layer 110 may be delaminated.

Here, the metal layer 111 and the first metal layer 110 may be delaminated using a blade, but the present disclosure is not limited thereto and any method known in the art may be used.

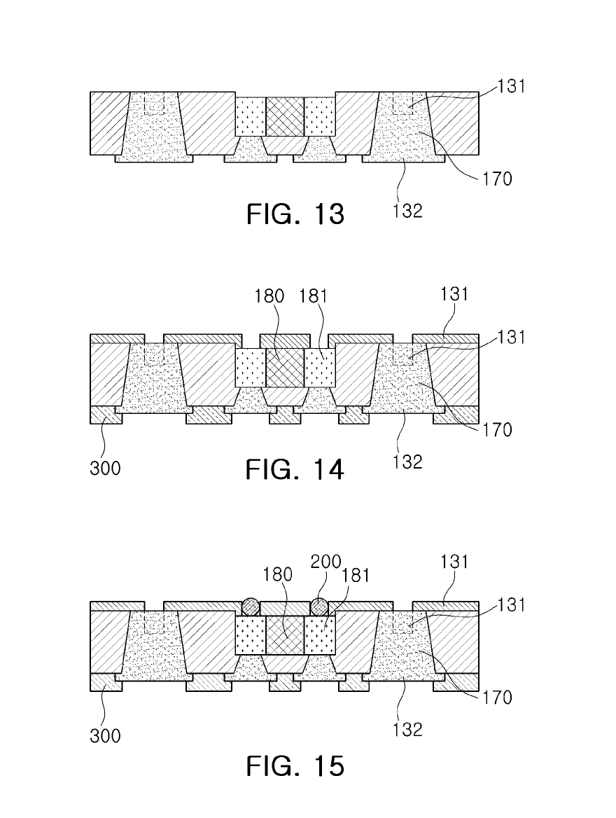

Referring to FIG. 13, the first metal layer 110 and the second metal layer 150 may be removed to expose the first circuit layer and the electronic component 180, and a second circuit layer including a second circuit pattern 132 may be formed.

Here, the first metal layer 110 and the second metal layer 150 may be removed through an etching process, but the present disclosure is not limited thereto.

During a process of etching the first metal layer 110, a level of an exposed upper surface of the first circuit pattern 131 may be equal to or lower than a level of the insulating layer 140. Here, when a level of the top surface of first circuit pattern 131 is lower than that of the insulating layer 140, a step may be formed.

Here, due to the step, solder is prevented from being fixed to be bridged with adjacent solder during a reflow process of forming a solder bump 200 on the first circuit pattern 131.

After the first metal layer 110 is removed, the adhesive tape 80 used to fix the electronic component 180 may be delaminated to be removed.

A level of an exposed upper surface of the electronic component 180 maybe equal to or lower than that of the insulating layer 140, so as to be embedded.

Only portions of the second metal layer 150 where the metal plating layer 132a is not formed may be selectively removed through general flash etching.

Although not shown, a build-up layer may be stacked on the second surface 142 of the insulating layer 140.

Here, in the drawing, the build-up layer 600 stacked on the second surface 142 of the insulating layer is illustrated as a dual-layer, but the build-up layer 600 may also be formed as a triple layer or a quadruple layer, or may be formed within the scope utilized by a person skilled in the art.

Referring to FIG. 14, solder resist layers 300 may be formed on both surfaces of the insulating layer 140 such that a circuit pattern for a connection pad of the first circuit layer and the second circuit layer is exposed.

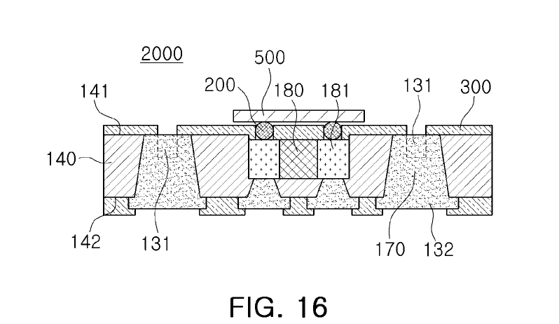

Referring to FIGS. 15 and 16, a solder bump 200 may be directly formed on the external electrode 181 on the exposed upper surface of the electronic component 180, and a surface mounting component 500 may be formed on the solder bump 200.

In the related art, an embedded electronic component is connected through via and a solder bump is formed on the via and connected to an external mounting device. In contrast, according to an exemplary embedment of the present disclosure, since the embedded electronic component is directly connected to an external mounting device through the solder bump, a shortest distance may be secured, enhancing electrical characteristics.

The surface mounting component 500 may be a component electrically connected to a PCB to provide a predetermined function. For example, the surface mounting component 500 may be an electronic component that may be directly mounted on a PCB, such as an integrated circuit (IC).

Other components of the surface mounting component 500 are omitted in the drawing, but surface mounting components having any structure known in the art may be used without a limitation.

As set forth above, according to exemplary embodiments of the present disclosure, since a circuit pattern is formed to serve as a land, whereby the circuit pattern may be embedded inside the via to form a larger amount of circuits within a limited region, manufacturing a high density product.

Also, by forming the circuit pattern such that a width thereof is smaller than a diameter of the via, only an upper surface of the first circuit pattern 131 is exposed outwardly and the other remaining three sides of the circuit pattern, excluding the upper surface, are embedded inside the via, enhancing electrical characteristics and reliability of the semiconductor package.

By embedding an electronic component, a thickness may be reduced, and by implementing a shortest distance between the embedded electronic component and a surface mounting component, noise may be reduced and electrical characteristics may be enhanced.

While exemplary embodiments have been shown and described above, it will be apparent to those skilled in the art that modifications and variations could be made without departing from the spirit and scope of the present disclosure as defined by the appended claims.

What is claimed is:

1. A printed circuit board comprising:
an insulating layer;
a first circuit layer including a first circuit pattern embedded therein such that an upper surface thereof is exposed to a first surface of the insulating layer;
a second circuit layer including a second circuit pattern formed on a second surface of the insulating layer;
a via electrically connecting the first circuit pattern and the second circuit pattern and formed in the insulating layer such that the first circuit pattern is embedded; and
an electronic component embedded inside the insulating layer and having an upper surface exposed to the first surface of the insulating layer.

2. The printed circuit board of claim 1, wherein a level of the top surface of first circuit pattern is equal to or lower than that of the insulating layer.

3. The printed circuit board of claim 1, wherein the first circuit pattern serves as a land.

4. The printed circuit board of claim 1, wherein a width of the first circuit pattern is smaller than or equal to a diameter of the via.

5. The printed circuit board of claim 1, wherein the first circuit pattern and the via are formed of the same material.

6. The printed circuit board of claim 1, wherein the electronic component is embedded such that a level of an upper surface thereof is equal to or lower than a level of the insulating layer.

7. The printed circuit board of claim 1, wherein a via is formed in a lower surface of the electronic component and electrically connected to the second circuit pattern.

8. The printed circuit board of claim 1, further comprising:
a solder bump formed on the exposed surface of the electronic component; and
an external mounting device formed on the solder bump so as to be mounted.

9. The printed circuit board of claim 1, further comprising:
a solder resist formed to expose a circuit pattern for a connection pad of the first circuit layer and the second circuit layer and the external electrode of the electronic component.

10. The printed circuit board of claim 1, further comprising a build-up layer stacked on the second surface of the insulating layer.

11. A semiconductor package comprising:
an insulating layer; a first circuit layer including a first circuit pattern embedded therein, such that an upper surface thereof is exposed to a first surface of the insulating layer;
a second circuit layer including a second circuit pattern formed on a second surface of the insulating layer;
a via electrically connecting the first circuit pattern and the second circuit pattern and formed in the insulating layer such that the first circuit pattern is embedded;
a stacked-type electronic component embedded inside the insulating layer and having an external electrode exposed to the first surface of the insulating layer;
a solder bump formed on the external electrode; and
a surface mounting component formed on the solder bump so as to be mounted.

12. A method of manufacturing a printed circuit board (PCB), the method comprising:
preparing a carrier board having a least one surface on which a first metal layer is formed;
forming a first circuit layer including a first circuit pattern and an electronic component on at least one surface of the first metal layer;
forming an insulating layer on the first circuit layer and the electronic component;
forming a via hole such that the first circuit pattern and an external electrode of the electronic component are exposed;
forming a via and a patterned metal plating layer such that the first circuit pattern is embedded and the external electrode is electrically connected;
delaminating the first metal layer from the carrier board; and
removing the first metal layer to expose the first circuit layer and the electronic component.

13. The method of claim 12, wherein a level of the top surface of first circuit pattern is equal to or lower than that of the insulating layer.

14. The method of claim 12, wherein the first circuit pattern serves as a land.

15. The method of claim 12, wherein a width of the first circuit pattern is smaller than or equal to a diameter of the via.

16. The method of claim 12, wherein the via and the first circuit pattern are formed of the same material.

17. The method of claim 12, further comprising:
forming a second circuit layer on a surface of the insulating layer opposite a surface on which the first circuit layer is formed; and
forming a build-up layer on the second circuit layer.

18. The method of claim 12, wherein an electronic component is attached using an adhesive tape on both surfaces of the first metal layer.

19. The method of claim 18, wherein the adhesive tape is removed when the first metal layer is removed.

20. A method of manufacturing a printed circuit board (PCB), the method comprising:
preparing a carrier board having a least one surface on which a first metal layer is formed;
forming a first circuit layer including a first circuit pattern and an electronic component on both surfaces of the first metal layer;
forming an insulating layer on the first circuit layer and the electronic component;
forming a via hole such that the first circuit pattern and an external electrode of the electronic component are exposed;
forming a via and a patterned metal plating layer such that the first circuit pattern is embedded and the external electrode is electrically connected;
delaminating the first metal layer from the carrier board;
removing the first metal layer to expose the first circuit layer and the electronic component;
forming a solder bump on an exposed surface of the electronic component; and
mounting a surface mounting component on the solder bump.

21. A printed circuit board (PCB) comprising:
an insulating layer;
an electronic component embedded in the insulating layer; and
a solder bump formed on an electrode of the electronic component.

22. The printed circuit board of claim 21, wherein a solder resist is formed in at least a portion of the electronic component.
